(19) United States
(12) Patent Application Publication
(10) Pub. No.: US 2026/0264607 A1
(43) Pub. Date: Sep. 10, 2026

(54) SUBSTRATE FOR ILLUMINATION DEVICE WITH HEAT DISSIPATION WIRING

(71) Applicant: TOYODA GOSEI CO., LTD., Kiyosu-shi (JP)

(72) Inventors: Kazuma MURAMATSU, Aichi (JP); Akitoshi NAGANAWA, Aichi (JP); Masaaki MORI, Aichi (JP); Yuko SAKURAI, Aichi (JP); Tsukasa KITAZAWA, Aichi (JP)

(21) Appl. No.: 19/549,415

(22) Filed: Feb. 25, 2026

(30) Foreign Application Priority Data
Mar. 10, 2025 (JP) 2025-037553

(51) Int. Cl. B60Q 3/283; B60Q 3/80; H10H 29/24; H10H 29/80; H10H 29/85; B60Q 3/62; H10H 29/855

(52) U.S. Cl. CPC B60Q 3/283; B60Q 3/80; H10H 29/24; H10H 29/857; H10H 29/8581; H10H 29/8582; H10H 29/8585; H10H 29/942; B60Q 3/62; H10H 29/855

(57) ABSTRACT

A substrate for an illumination device to be mounted on a steering wheel, includes: a substrate main body; a light emitting element provided on a surface of the substrate main body; and a heat dissipation wiring including a material having a higher thermal conductivity than a thermal conductivity of the substrate main body, the heat dissipation wiring being provided in an installation portion that is at least one of: inside of the substrate main body; or an outer surface of the substrate main body, and the heat dissipation wiring being configured to dissipate heat generated from the light emitting element.

### CROSS-REFERENCE TO RELATED APPLICATION

This application is based on and claims priority under 35 USC 119 from Japanese Patent Application No. 2025-037553 filed on Mar. 10, 2025.

### TECHNICAL FIELD

The present disclosure relates to a substrate for an illumination device to be mounted on a steering wheel.

### BACKGROUND ART

It has been proposed to attach a device (hereinafter, referred to as an "illumination device") that emits light such as visible light and infrared light to a steering wheel at a position viewable to a driver and use the device. In such an illumination device, a substrate provided with a light emitting element such as an LED may be used. In the steering wheel according to Patent Literature 1, a substrate is disposed in indirect contact with a cored bar via a heat conduction member. With such a configuration, heat of the light emitting element is transferred to the cored bar via the heat conduction member and is dissipated.

Patent Literature 1: Japanese Patent Application Publication No. 2020-508913

### SUMMARY

In the steering wheel according to Patent Literature 1, it is necessary to bring the substrate, the heat conduction member, and the cored bar into contact with each other. However, these members may not come into contact with each other due to an assembly variation. In addition, there is also a problem that there are many limitations to component arrangement, such as it is necessary to dispose the substrate and the cored bar as close as possible, and it is impossible to dispose an electronic component on a back surface of the substrate. Therefore, there is a demand for a technique capable of improving the assembling property and the packaging property of the steering wheel while achieving heat dissipation of the light emitting element.

The present disclosure has been made to solve at least a part of the above problems, and can be implemented in the following aspects.

(1) An aspect of the present disclosure provides a substrate for an illumination device to be mounted on a steering wheel. The substrate includes a substrate main body; a light emitting element provided on a surface of the substrate main body; and a heat dissipation wiring formed of a material having a higher thermal conductivity than the substrate main body, the heat dissipation wiring is provided in an installation portion that is at least one of inside of the substrate main body and an outer surface of the substrate main body, and the heat dissipation wiring is used to dissipate heat generated from the light emitting element.

According to the substrate of this aspect, the heat dissipation wiring is included, which is formed of the material having a higher thermal conductivity than the substrate main body is included, is provided in the installation portion that is at least one of the inside of the substrate main body and the outer surface of the substrate main body, and is used to dissipate the heat generated from the light emitting element, and thus it is possible to omit an operation of bringing the substrate into contact with the heat conduction member or the cored bar in order to dissipate the heat of the light emitting element, and it is possible to prevent a disposition position of the substrate from being limited due to the heat dissipation. Therefore, it is possible to improve the assembling property and the packaging property of the steering wheel while achieving the heat dissipation of the light emitting element.

(2) In the substrate according to the above aspect, the heat dissipation wiring may serve as a power supply wiring for supplying power to the light emitting element.

According to the substrate of this aspect, since the heat dissipation wiring serves as the power supply wiring for supplying power to the light emitting element, the substrate can be miniaturized and integrated as compared with a configuration in which the heat dissipation wiring is separately provided as a dedicated wiring from the power supply wiring.

(3) In the substrate according to the above aspect, the substrate main body may have an external shape in which a pair of arc-shaped outer edges along a circumferential direction of an annular grip portion of the steering wheel are positioned apart from each other in a radial direction of the grip portion, the light emitting element may include a pair of first light emitting elements respectively provided at end portions of the substrate main body along the circumferential direction, and a second light emitting element provided between the pair of first light emitting elements in the circumferential direction and provided at a position different from the positions of the pair of first light emitting elements in the radial direction, and the heat dissipation wiring may be provided between the pair of first light emitting elements in the circumferential direction, and may be provided at a position different from the position of the second light emitting element in the radial direction.

According to the substrate of this aspect, since the heat dissipation wiring is provided between the pair of first light emitting elements in the circumferential direction and is provided at the position different from the position of the second light emitting element in the radial direction, the heat dissipation wiring can be disposed by using a free region that does not interfere with the disposition positions of the pair of light emitting elements and the second light emitting element. Therefore, it is possible to secure a larger surface area of the heat dissipation wiring and improve heat dissipation efficiency.

(4) In the substrate according to the above aspect, the installation portion may include the outer surface, and the heat dissipation wiring may be disposed to be bent along the outer surface.

According to the substrate of this aspect, since the installation portion includes the outer surface, the heat of the light emitting element can be efficiently dissipated to the outside. Further, since the heat dissipation wiring is disposed to be bent along the outer surface, the larger surface area of the heat dissipation wiring can be secured as compared with a configuration in which the heat dissipation wiring is disposed linearly.

(5) In the substrate according to the above aspect, the heat dissipation wiring may be provided to include a plurality of bent portions or a plurality of curved portions.

According to the substrate of this aspect, since the heat dissipation wiring is provided to include a plurality of bent portions or a plurality of curved portions, the larger surface area of the heat dissipation wiring can be secured as compared with a configuration in which the heat dissipation wiring is bent as a whole without a plurality of bent portions or a plurality of curved portions.

(6) In the substrate according to the above aspect, the substrate main body may have a configuration in which a plurality of layers are stacked, the installation portion may include a boundary surface between two adjacent layers among the plurality of layers, and the heat dissipation wiring may be disposed to be bent along the boundary surface.

According to the substrate of this aspect, since the substrate main body has the configuration in which a plurality of layers are stacked, the installation portion includes the boundary surface between two adjacent layers among the plurality of layers, and the heat dissipation wiring is disposed to be bent along the boundary surface, another wiring or element different from the heat dissipation wiring can be disposed on a boundary surface at another layer of the substrate main body or the outer surface of the substrate main body.

(7) In the substrate according to the above aspect, the heat dissipation wiring may be provided to include a plurality of bent portions or a plurality of curved portions.

According to the substrate of this aspect, since the heat dissipation wiring is provided to include a plurality of bent portions or a plurality of curved portions, the larger surface area of the heat dissipation wiring can be secured as compared with the configuration in which the heat dissipation wiring is bent as a whole without a plurality of bent portions or a plurality of curved portions.

### BRIEF DESCRIPTION OF DRAWINGS

FIG. 1 is a plan view showing an external shape of a steering wheel to which a substrate as an embodiment of the present disclosure is applied;

FIG. 2 is a plan view showing an external shape of the steering wheel in a state in which a lens member, a light guiding member, and a base member are removed;

FIG. 3 is a first exploded perspective view showing a detailed configuration of an illumination device;

FIG. 4 is a second exploded perspective view showing the detailed configuration of the illumination device;

FIG. 5 is an explanatory diagram showing a detailed configuration of the substrate;

FIG. 6 is an explanatory diagram showing a detailed configuration of a substrate according to a second embodiment; and

FIG. 7 is an explanatory diagram showing a detailed configuration of a substrate according to a third embodiment.

### DESCRIPTION OF EMBODIMENTS

### A. First Embodiment

### A1. Overall Configuration of Steering Wheel 100

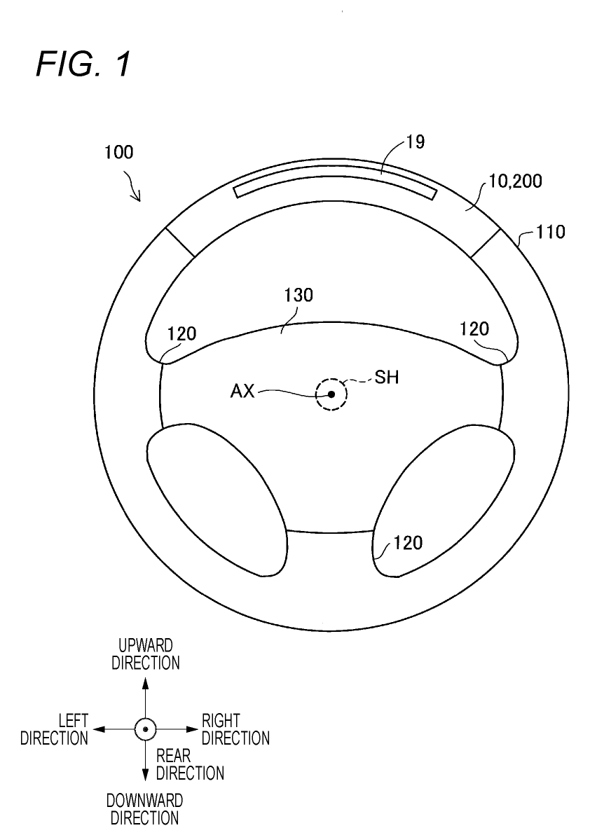

FIG. 1 is a plan view showing an external shape of a steering wheel 100 to which a substrate (a substrate 31 to be described later) as an embodiment of the present disclosure is applied. The steering wheel 100 is disposed in a driver's seat area of a vehicle and is used by a driver. Examples of the vehicle include a vehicle equipped with an engine, a hybrid vehicle (HEV), a plug-in hybrid vehicle (PHEV), a battery electric vehicle (BEV), and a fuel cell vehicle (FCV). The steering wheel 100 is a part of a steering apparatus that is operated by the driver of the vehicle. FIG. 1 shows the steering wheel 100 in a state of being coupled to a steering shaft SH in the vehicle and causing the vehicle to travel straight (hereinafter, also referred to as a "reference state"). FIG. 1 shows an external configuration of the steering wheel 100 on a side facing the driver (a "rear direction" side to be described later). The steering wheel 100 is configured to enable a rotation operation about an axis AX of the steering shaft SH. The rotation of the steering wheel 100 is transmitted to a steering gear box (not shown) via the steering shaft SH.

In the present embodiment, a direction along the axis AX of the steering shaft SH is referred to as a "front-rear direction" (a front direction and a rear direction) in association with a traveling direction of the vehicle. Among directions orthogonal to the axis AX, a direction overlapping with a vertical direction (a vertically upward direction and a vertically downward direction) when viewed by the driver is referred to as an "upward-downward direction". Among the directions orthogonal to the axis AX, a direction parallel to left and right directions (a width direction) of the vehicle is referred to as a "left-right direction".

The steering wheel 100 includes a ring-shaped grip portion 110, a boss portion 130 disposed at a substantially central portion of the grip portion 110, three spoke portions 120, and an illumination device 200 disposed at a part of the grip portion 110.

The grip portion 110 is gripped by the driver when the steering wheel 100 is operated. In the present embodiment, the grip portion 110 has a substantially circular ring shape. A center axis of the grip portion 110 coincides with the axis AX of the steering shaft SH. The shape of the grip portion 110 may be any shape such as a polygonal shape and an elliptical shape instead of the substantially circular ring shape, and may be a non-symmetrical shape such as a so-called D shape. Further, the shape of the grip portion 110 is not limited to an annular shape, and may be any shape formed by a plurality of parts provided at positions separated from each other. The grip portion 110 is configured by stacking a plurality of members in a thickness direction. Specifically, a cored bar formed of a metal such as an aluminum alloy is disposed at a substantially central position of the grip portion 110. Further, a shock absorbing material made of a soft foamed material having a cushioning property covers the cored bar. An outer surface of the shock absorbing material is covered with an element layer provided with an electric heating wire for a heater, an electrode for detecting gripping, and the like. Then, an outer skin layer 80 made of a leather member such as natural leather or synthetic leather is formed on a surface of a member on which the element layer is formed and a surface of the illumination device 200 (a base member to be described later) assembled to the member. In the present embodiment, the outer skin layer 80 is not formed on a surface of a lens member (a lens member 10) to be described later in the illumination device 200. Although not shown in FIG. 1, in the grip portion 110, a recess (a recess C1 to be described later) is formed in a part of the grip portion 110 on the upper side in the reference state. A part of the illumination device 200 is accommodated in the recess, and the recess is closed.

The three spoke portions 120 couple the grip portion 110 and the boss portion 130. The boss portion 130 corresponds to a connection portion when the steering wheel 100 is connected to the steering shaft SH. A folded air bag and an inflator, which are not shown, are accommodated in the boss portion 130. Further, a temperature control circuit constituting a heater, and various sensor devices for detecting room temperature and gripping of the grip portion 110 by a user may be accommodated in the boss portion 130. The three spoke portions 120 and the boss portion 130 may be provided with various operation buttons for operating a navigation device, an audio device, and the like mounted on the vehicle.

The illumination device 200 emits light. In the present embodiment, the light emitted by the illumination device 200 includes visible light and infrared light (infrared rays). By emitting the visible light from the illumination device 200, the driver can be notified of various information. In addition, by emitting the infrared light from the illumination device 200, a part of the body of the driver can be clearly photographed by an infrared camera in a dark vehicle cabin at night.

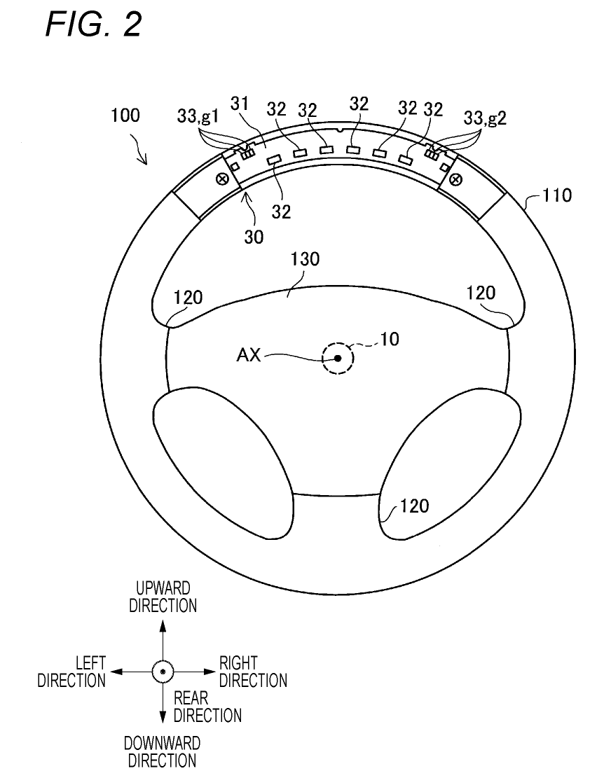

FIG. 2 is a plan view showing an external shape of the steering wheel 100 in a state in which the lens member 10, a light guiding member 20, and a base member 40 are removed. As described below, in the illumination device 200, the lens member 10 having light transmission is disposed at a position facing the driver, and the light guiding member 20 and the base member 40, which will be described later, are disposed on the front direction side of the lens member 10. FIG. 2 schematically shows the steering wheel 100 in the state in which the lens member 10, the light guiding member 20, and the base member 40 are removed.

As shown in FIG. 2, when the lens member 10, the light guiding member 20, and the base member 40 are removed, a light emitting portion 30, which is one of components constituting the illumination device 200, is exposed. The light emitting portion 30 includes the substrate 31 and a plurality of light emitting elements provided on a surface of the substrate 31. In the present embodiment, the "plurality of light emitting elements" include a plurality of first LEDs 32 and a plurality of second LEDs 33. The substrate 31 has an arc-like and belt-like external shape that is curved along a circumferential direction of the grip portion 110 (hereinafter, also simply referred to as the "circumferential direction") when viewed by the driver. In other words, the substrate 31 has an external shape in which a pair of arc-shaped outer edges along the circumferential direction are positioned apart from each other in a radial direction of the grip portion 110 (hereinafter, also simply referred to as the "radial direction"). The "radial direction" is a direction orthogonal to the axis AX, and can also be referred to as a radial direction of the steering wheel 100.

The plurality of first LEDs 32 are disposed at positions close to an end portion on the downward direction side of the surface of the substrate 31 on the rear direction side so as to be separated from each other by a predetermined distance along the circumferential direction. The first LEDs 32 emit the visible light. In the present embodiment, a visible light LED capable of emitting red light, green light, and blue light is used as the first LED 32. The plurality of first LEDs 32 correspond to a "second light emitting element" according to the present disclosure.

The plurality of second LEDs 33 form two groups g1 and g2 disposed to be separated from each other. Each of the groups g1 and g2 includes a plurality of second LEDs 33 adjacent to each other in the circumferential direction. Each of the two groups g1 and g2 is disposed at an end portion on the upward direction side of the surface of the substrate 31 on the rear direction side. The two groups g1 and g2 are disposed to be separated from each other so as to sandwich the plurality of first LEDs 32 when viewed along the circumferential direction. In other words, the plurality of first LEDs 32 are provided between the groups g1 and g2, and are provided at positions different from the positions of the groups g1 and g2 in the radial direction. The second LEDs 33 emit the infrared light. Each of the groups g1 and g2 may include only one second LED 33. The second LEDs 33 correspond to a "first light emitting element" according to the present disclosure. Further, the two groups g1 and g2 correspond to a "pair of first light emitting elements" according to the present disclosure.

In addition to the plurality of first LEDs 32 and the plurality of second LEDs 33 described above, the substrate 31 is provided with power supply wirings, heat dissipation wirings (heat dissipation wirings L1 to L7, L11, and L12 to be described later), and connectors (connectors CN1 and CN2 to be described later) for the respective LEDs 32 and 33, which are omitted in FIG. 2.

### A2. Detailed Configuration of Illumination Device 200

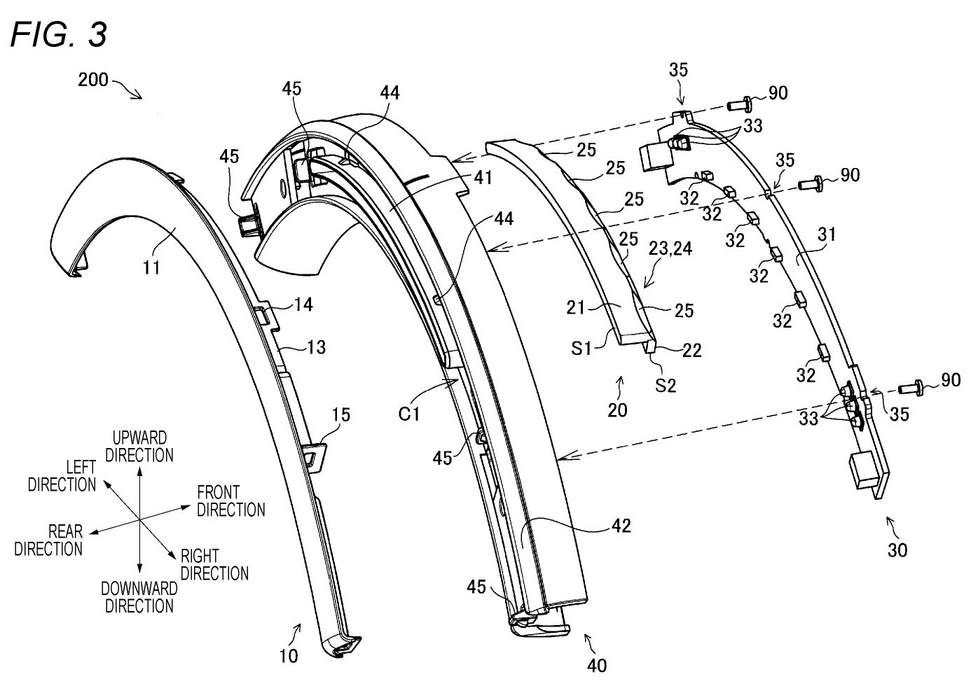

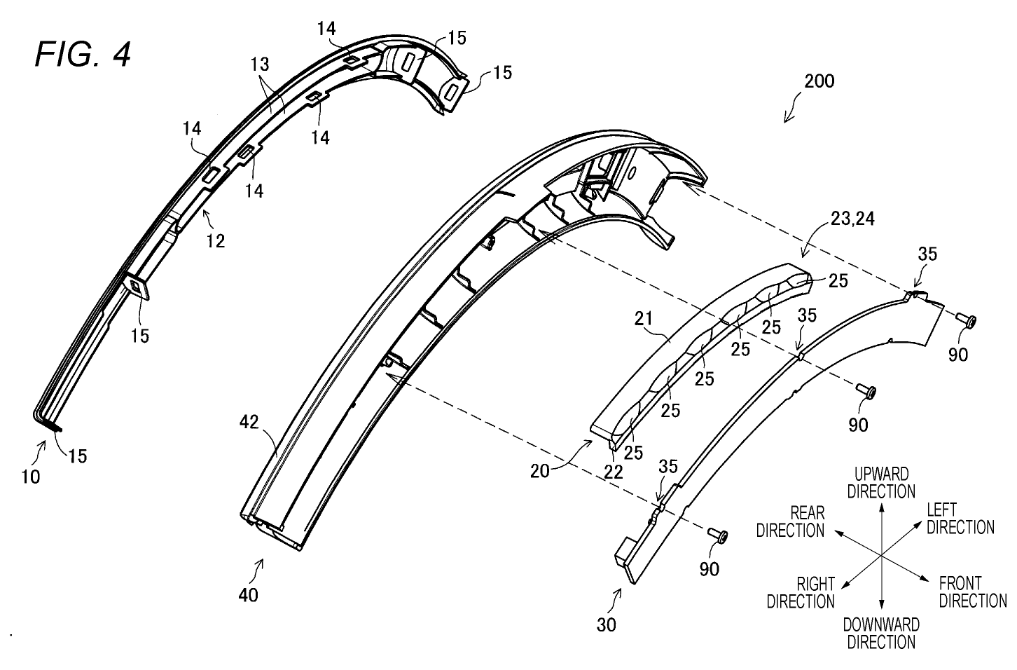

FIG. 3 is a first exploded perspective view showing a detailed configuration of the illumination device 200. FIG. 4 is a second exploded perspective view showing the detailed configuration of the illumination device 200. FIG. 3 corresponds to an exploded perspective view of the illumination device 200 viewed substantially from the rear side toward the front side. FIG. 4 corresponds to an exploded perspective view of the illumination device 200 viewed substantially from the front side toward the rear side.

As shown in FIGS. 3 and 4, the illumination device 200 includes the lens member 10, the light guiding member 20, and the base member 40 in addition to the light emitting portion 30 described above. The illumination device 200 has a structure in which the light guiding member 20 and the light emitting portion 30, and the lens member 10 are integrally assembled in the front-rear direction with the base member 40 sandwiched therebetween.

As shown in FIGS. 3 and 4, the lens member 10 includes a second emission surface 11, a surrounding portion 12, and a plurality of engaging walls 15. The second emission surface 11 shown in FIG. 3 forms an outer surface of the steering wheel 100 continuously with the outer skin layer 80. Similarly to the substrate 31 described above, the second emission surface 11 has an arc-like and belt-like external shape that is curved along the circumferential direction of the grip portion 110 when viewed by the driver. The second emission surface 11 is transparent to the visible light and the infrared light. In the present embodiment, the second emission surface 11 has a transmittance of about 25% with respect to the visible light and a transmittance of about 90% with respect to the infrared light. Each of the transmittances with respect to the visible light and the infrared light may be any value higher than 0%. In the present embodiment, the second emission surface 11 is made of a black transparent synthetic resin in accordance with the black outer skin layer 80. The second emission surface 11 may be covered with the outer skin layer 80. In such a configuration, the outer skin layer 80 has light transmission, and thus the second emission surface 11 can diffuse the visible light emitted from the first LEDs 32 into the vehicle cabin.

The second emission surface 11 has, in addition to a function of protecting the light emitting portion 30, a function of limiting a region through which the visible light emitted from the first LEDs 32 is transmitted (in other words, a function of masking a region which is not desired to be illuminated), and a function of deflecting an emission direction of the infrared light emitted from the second LEDs 33 to be directed to the upper side on the rear direction side which is a driver side. Further, the second emission surface 11 may have a function of diffusing the visible light emitted from the first LEDs 32. A light emitting region 19 shown in FIG. 1 is a region through which the visible light is transmitted. On the other hand, in FIG. 1, a region of the second emission surface 11 other than the light emitting region 19 is a region in which transmission of the visible light is limited. In FIG. 3, the light emitting region 19 is not shown.

As shown in FIG. 4, the surrounding portion 12 is provided on a surface (a back surface) of the second emission surface 11 on the front direction side. In a state in which the illumination device 200 is assembled (hereinafter, also simply referred to as an "assembled state"), the surrounding portion 12 is disposed to surround a transmission inhibition portion 41 protruding from the recess C1 of the base member 40 shown in FIG. 3 toward the rear direction side, and a first light passage portion 21 (to be described later) corresponding to a part of the light guiding member 20 accommodated in the transmission inhibition portion 41 over the entire periphery. The recess C1 has a groove-shaped structure that opens into a surface of the base member 40 in the front direction and extends along the circumferential direction. In the surrounding portion 12, a protrusion 13 corresponding to a side wall along the radial direction protrudes from the surface of the second emission surface 11 on the front direction side, that is, the inner surface to a depth direction of the recess C1. As shown in FIG. 4, a plurality of engaging holes 14 are formed in the protrusion 13. In the assembled state, engaging claws 44 (see FIG. 3) provided in an outer peripheral surface of the transmission inhibition portion 41 of the base member 40 are engaged with the engaging holes 14. As shown in FIG. 4, each of the plurality of engaging walls 15 has a thin wall-like external shape protruding in the front direction, and is provided with an engaging hole. In the assembled state, the engaging walls 15 are disposed in contact with engaging walls 45 (see FIG. 3) of the base member 40. Further, in the assembled state, engaging claws provided in the engaging walls 45 are engaged with the engaging holes of the engaging walls 15.

The light guiding member 20 guides the light (the visible light) emitted from the first LEDs 32 to the lens member 10. In the present embodiment, the light guiding member 20 is made of a polycarbonate (PC) resin. The light guiding member 20 may be made of an acrylic resin instead of the PC resin. As shown in FIGS. 3 and 4, the light guiding member 20 has an external shape whose cross-sectional shape along the axis AX is a substantially L shape. In addition, the light guiding member 20 has an arc-like external shape in accordance with disposed positions of the plurality of first LEDs 32 when viewed by the driver.

As shown in FIGS. 3 and 4, the light guiding member 20 includes the first light passage portion 21, a second light passage portion 22, and a deflection portion 23. The first light passage portion 21 includes a first emission surface S1 through which the visible light is emitted from the light guiding member 20 to the lens member 10. The first light passage portion 21 extends along a direction from the surface (the surface on the rear direction side) of the substrate 31 toward the lens member 10. In the present embodiment, the first emission surface S1 is a flat surface, and diffused light having a spread is output as emitted light from the first emission surface S1. The emitted light from the first emission surface S1 is received by the lens member 10, and is emitted from the second emission surface 11 to the outside.

The second light passage portion 22 has an incident surface S2 on which the visible light output from the first LEDs 32 is incident. The deflection portion 23 connects the first light passage portion 21 and the second light passage portion 22, reflects the visible light derived from the second light passage portion 22, and inputs the reflected visible light to the first light passage portion 21. More specifically, the deflection portion 23 deflects the visible light, which is incident on the second light passage portion 22 from the incident surface S2 and runs upward, forward, and inputs the deflected visible light to the first light passage portion 21. As shown in FIG. 4, the deflection portion 23 has a deflection surface 24 that deflects the visible light. A plurality of diffusion portions 25 are formed on the deflection surface 24. The diffusion portions 25 are disposed at positions corresponding to the first LEDs 32 on the front side. Each diffusion portion 25 has a recessed structure obtained by partially chamfering the deflection surface 24.

The base member 40 holds the light guiding member 20 and the light emitting portion 30 attached to the front direction side thereof, and holds the lens member 10 attached to the rear direction side thereof. As shown in FIGS. 3 and 4, the base member 40 has an arc-like and belt-like external shape that is curved along the circumferential direction when viewed by the driver. In the present embodiment, the base member 40 is configured as a single component made of an ABS resin. The base member 40 may be configured as a single component made of a PC resin instead of the ABS resin or in addition to the ABS resin. Alternatively, the base member 40 may be configured as a composite component obtained by combining a plurality of components.

In the recess C1, a through hole penetrating in the thickness direction is formed in a portion corresponding to the light guiding member 20. The first light passage portion 21 of the light guiding member 20 is inserted into such a through hole. As shown in FIG. 3, in the recess C1, the above transmission inhibition portion 41 is provided to surround the through hole into which the first light passage portion 21 is inserted. Similarly to the surrounding portion 12 of the lens member 10 shown in FIG. 4, the transmission inhibition portion 41 includes a through hole and is formed to protrude in the front direction so as to cover a side surface of the first light passage portion 21 inserted into such a through hole in a contact state over the entire periphery. The transmission inhibition portion 41 inhibits the transmission of the visible light, similarly to other portions of the base member 40.

### A3. Detailed Configuration of Substrate 31

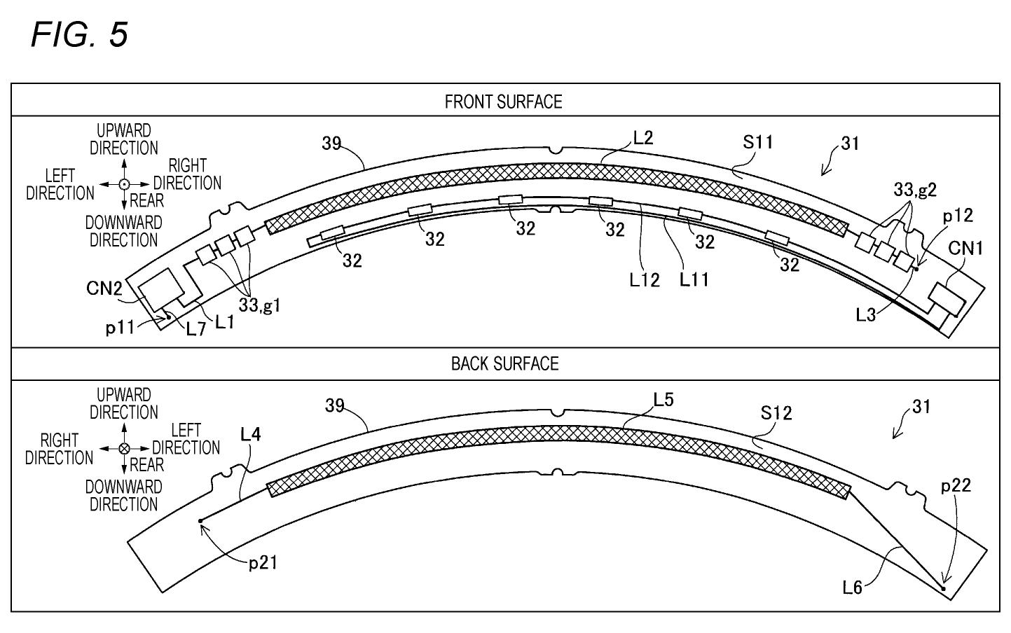

FIG. 5 is an explanatory diagram showing a detailed configuration of the substrate 31. In FIG. 5, the upper part shows a detailed configuration of a front surface S11 (the surface on the rear direction side) of the substrate 31, and the lower part shows a detailed configuration of a back surface S12 (a surface on the front direction side) of the substrate 31.

The substrate 31 is a so-called printed circuit board (PCB), and includes a substrate main body 39, the two connectors CN1 and CN2, and the heat dissipation wirings L1 to L7, L11, and L12 in addition to the plurality of first LEDs 32 and the plurality of second LEDs 33 described above. The substrate main body 39 is a member on which various wirings and elements are provided. In addition to the two connectors CN1 and CN2 and the heat dissipation wirings L1 to L7, L11, and L12, vias (not shown) arranged in the thickness direction are provided in the substrate main body 39.

The connector CN1 is disposed at a right end portion of the front surface S11 of the substrate 31 in the circumferential direction. The connector CN1 is a connector for supplying power to the plurality of first LEDs 32. A terminal of a power supply wiring provided outside the substrate 31 is connected to the connector CN1. Such a terminal reaches the grip portion 110 via the boss portion 130 and the spoke portions 120, and is disposed along the circumferential direction inside the grip portion 110. The connector CN1 is provided with the pair of heat dissipation wirings L11 and L12 for connecting the plurality of first LEDs 32 in series.

The connector CN2 is disposed at a left end portion of the front surface S11 of the substrate 31 in the circumferential direction. The connector CN2 is a connector for supplying power to the plurality of second LEDs 33. A terminal of a power supply wiring provided outside the substrate 31 is connected to the connector CN2. Such a terminal is a terminal of a power supply wiring that reaches the grip portion 110 via the boss portion 130 and the spoke portions 120, and is disposed along the circumferential direction inside the grip portion 110. The heat dissipation wirings L1 and L7 are connected to the connector CN2. In the present embodiment, similarly to the plurality of first LEDs 32, the plurality of second LEDs 33 are connected in series to each other.

The pair of heat dissipation wirings L11 and L12 are also used as power supply wirings for the plurality of first LEDs 32. The pair of heat dissipation wirings L11 and L12 are connected to the respective first LEDs 32. Heat of the respective first LEDs 32 is transferred to the pair of heat dissipation wirings L11 and L12 connected to the respective first LEDs 32. The heat transferred to the heat dissipation wiring L11 is diffused to, for example, the substrate main body 39 or external air. The pair of heat dissipation wirings L11 and L12 and the heat dissipation wirings L1 to L7 are all formed of a material having a higher thermal conductivity than the substrate main body 39. Specifically, in the present embodiment, the heat dissipation wirings L1 to L7, L11, and L12 are formed of copper. Instead of copper, the heat dissipation wirings L1 to L7, L11, and L12 may be formed of any material having a higher thermal conductivity than the substrate main body 39, such as silver or tin.

The heat dissipation wiring L1 connects the connector CN2 and the group g1 (the plurality of second LEDs 33). The three second LEDs 33 constituting the group g1 are connected in series to each other.

The heat dissipation wiring L2 connects the group g1 and the group g2. The heat dissipation wiring L2 has an arc-like external shape as a whole along the circumferential direction. The heat dissipation wiring L2 is disposed between the two groups g1 and g2 in the circumferential direction, and is disposed above the plurality of first LEDs 32 in the radial direction. As shown in FIG. 5, the two groups g1 and g2 are located outside the plurality of first LEDs 32 in the radial direction. Therefore, it can be said that the heat dissipation wiring L2 is provided between the two groups g1 and g2 in the circumferential direction and at a position different from the positions of the plurality of first LEDs 32 in the radial direction. A region in which the heat dissipation wiring L2 is disposed can be referred to a so-called free region that does not interfere with the plurality of first LEDs 32 and the plurality of second LEDs 33. As shown in FIG. 5, the thickness of the heat dissipation wiring L2 is larger than the thicknesses of the heat dissipation wirings L1, L3, L4, L6, and L7. Even if the thickness of the heat dissipation wiring L2 is increased as described above, the heat dissipation wiring L2 is disposed in the above free region, and thus interference with other electronic components is inhibited. Moreover, since the thickness of the heat dissipation wiring L2 is larger, a larger surface area of the heat dissipation wiring L2 can be secured, and the heat dissipation efficiency can be improved. Further, since the heat dissipation wiring L2 connects the group g1 positioned at the left end portion and the group g2 positioned at the right end portion in the circumferential direction on the substrate 31, an extension distance is relatively large. By further increasing the thickness of the heat dissipation wiring L2 having such a relatively large extension distance, the heat dissipation efficiency can be further improved.

One end of the heat dissipation wiring L3 is connected to the group g2, and the other end thereof is connected to an end portion p12 of the via (not shown) on the rear direction side. As shown in the lower part of FIG. 5, an end portion p21 of such a via on the front direction side is positioned on the back surface S12 of the substrate 31.

The heat dissipation wiring L4 connects the end portion p21 and the heat dissipation wiring L5 to be described later. The heat dissipation wiring L5 is disposed at a position corresponding to the heat dissipation wiring L2 in the thickness direction of the substrate 31. Therefore, the heat dissipation wiring L5 is disposed to be bent along the circumferential direction, similarly to the heat dissipation wiring L2. Similarly to the heat dissipation wiring L2, the heat dissipation wiring L5 is configured to have a larger thickness than the thicknesses of the heat dissipation wirings L1, L3, L4, L6, and L7. Similarly to the heat dissipation wiring L2, by increasing the thickness of the heat dissipation wiring L5 having a larger extension distance, the heat dissipation efficiency can be improved.

One end of the heat dissipation wiring L6 is connected to the heat dissipation wiring L5, and the other end thereof is connected to an end portion p22 of the via (not shown) on the front direction side. As shown in the upper part of FIG. 5, an end portion p11 of such a via on the rear direction side is positioned on the front surface S11 of the substrate 31. One end of the heat dissipation wiring L7 is connected to the end portion p11, and the other end thereof is connected to the connector CN2.

In the first embodiment, the front surface S11 and the back surface S12 of the substrate 31 on which the heat dissipation wirings L1 to L7, L11, and L12 are provided correspond to an "installation portion" in the present disclosure.

In the substrate 31 according to the first embodiment described above, the heat dissipation wirings L1 to L7, L11, and L12 are included, which are heat dissipation wirings formed of the material having a higher thermal conductivity than the substrate main body 39, are provided in the installation portion that is the front surface S11 and the back surface S12 corresponding to an outer surface of the substrate main body 39, and are used to dissipate the heat generated from the plurality of first LEDs 32 and the plurality of second LEDs 33 that are light emitting elements, and thus it is possible to omit an operation of bringing the substrate 31 into contact with a heat conduction member or the cored bar in order to dissipate the heat of the plurality of first LEDs 32 and the plurality of second LEDs 33, and it is possible to prevent the disposition position of the substrate 31 from being limited due to the heat dissipation. Therefore, it is possible to improve the assembling property and the packaging property of the steering wheel 100 while achieving the heat dissipation of the plurality of first LEDs 32 and the plurality of second LEDs 33.

In addition, since the heat dissipation wirings L1 to L7, L11, and L12 serve as the power supply wirings for supplying power to the plurality of first LEDs 32 and the plurality of second LEDs 33, the substrate 31 can be miniaturized and integrated as compared with a configuration in which the heat dissipation wirings L1 to L7, L11, and L12 are provided as dedicated wirings.

In addition, since the heat dissipation wirings L2 and L5 are provided between the pair of groups g1 and g2 in the circumferential direction and at positions different from the positions of the plurality of first LEDs 32 in the radial direction, the heat dissipation wirings L2 and L5 can be disposed by using the free region that does not interfere with the disposition positions of the pair of groups g1 and g2 and the plurality of first LEDs 32. Therefore, it is possible to increase the thicknesses of the heat dissipation wirings L2 and L5 to secure larger surface area, and improve the heat dissipation efficiency.

In addition, since the installation portion (the front surface S11 and the back surface S12) in which the plurality of first LEDs 32 and the plurality of second LEDs 33 are provided is the outer surface of the substrate main body 39, the heat of the plurality of first LEDs 32 and the plurality of second LEDs 33 can be efficiently dissipated. Further, since the heat dissipation wirings L2 and L5 are disposed to be bent along the front surface S11 and the back surface S12 of the substrate 31, respectively, it is possible to secure the larger surface areas of the heat dissipation wirings L2 and L5 as compared with a configuration in which the heat dissipation wirings L2 and L5 are disposed linearly.

### B. Second Embodiment

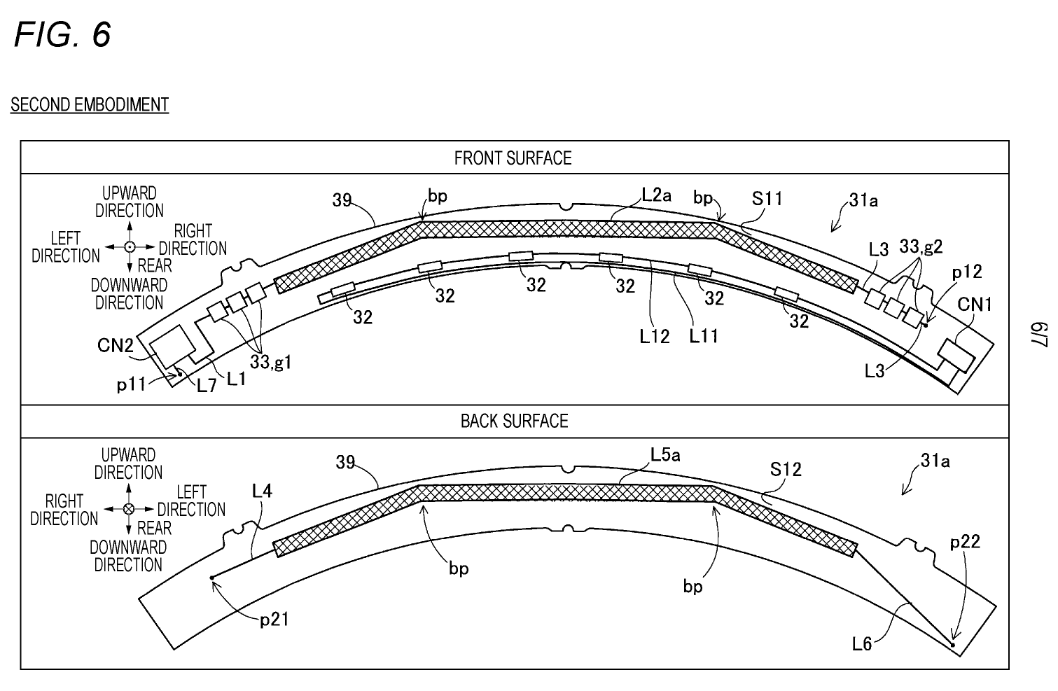

FIG. 6 is an explanatory diagram showing a detailed configuration of a substrate 31a according to a second embodiment. In FIG. 6, the upper part shows a detailed configuration of the front surface S11 of the substrate 31a according to the second embodiment, and the lower part shows a detailed configuration of the back surface S12 of the substrate 31a. The steering wheel 100 and the illumination device 200 according to the second embodiment are different from the steering wheel 100 and the illumination device 200 according to the first embodiment in that the substrate 31a is provided instead of the substrate 31. Since other components of the steering wheel 100 and the illumination device 200 according to the second embodiment are the same as those of the steering wheel 100 and the illumination device 200 according to the first embodiment, the same components are denoted by the same reference numerals, and detailed description thereof is omitted.

The substrate 31a is different from the substrate 31 according to the first embodiment only in that a heat dissipation wiring L2a and a heat dissipation wiring L5a are provided instead of the heat dissipation wiring L2 and the heat dissipation wiring L5. The heat dissipation wiring L2a according to the second embodiment is provided to include a plurality of bent portions bp. Specifically, as shown in the upper part of FIG. 6, the heat dissipation wiring L2a includes two bent portions bp. Each bent portion bp corresponds to an end portion (a vertex) common to two linear portions. As shown in the upper part of FIG. 6, it can be said that the heat dissipation wiring L2a is disposed to be bent substantially along the front surface S11. Similarly to the heat dissipation wiring L2a, the heat dissipation wiring L5a includes two bent portions bp, and is disposed to be bent substantially along the back surface S12.

The substrate 31a according to the second embodiment described above achieves the same effects as the substrate 31 according to the first embodiment. In addition, since the heat dissipation wirings L2a and L5a are provided to include the bent portions bp, larger surface areas of the heat dissipation wirings L2a and L5a can be secured as compared with a configuration in which the heat dissipation wirings L2a and L5a are bent as a whole without a plurality of bent portions bp or a configuration in which the heat dissipation wirings L2a and L5a are provided in a linear shape without a plurality of bent portions bp.

### C. Third Embodiment

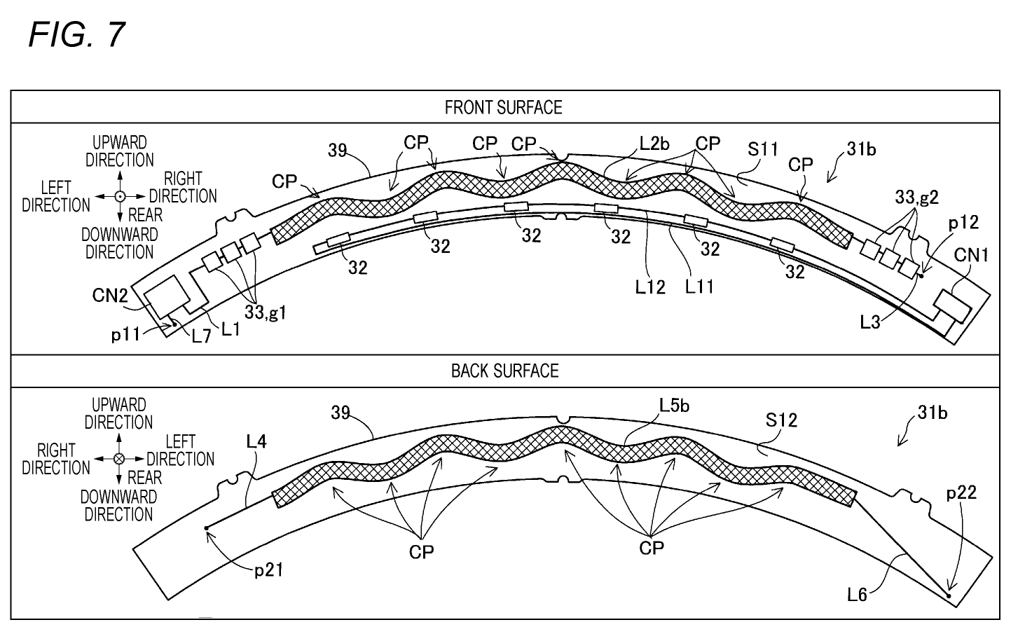

FIG. 7 is an explanatory diagram showing a detailed configuration of a substrate 31b according to a third embodiment. In FIG. 7, the upper part shows a detailed configuration of the front surface S11 of the substrate 31b according to the third embodiment, and the lower part shows a detailed configuration of the back surface S12 of the substrate 31b. The steering wheel 100 and the illumination device 200 according to the third embodiment are different from the steering wheel 100 and the illumination device 200 according to the first embodiment in that the substrate 31b is provided instead of the substrate 31. Since other components of the steering wheel 100 and the illumination device 200 according to the third embodiment are the same as those of the steering wheel 100 and the illumination device 200 according to the first embodiment, the same components are denoted by the same reference numerals, and detailed description thereof is omitted.

The substrate 31b is different from the substrate 31 according to the first embodiment only in that a heat dissipation wiring L2b and a heat dissipation wiring L5b are provided instead of the heat dissipation wiring L2 and the heat dissipation wiring L5. The heat dissipation wiring L2b according to the third embodiment is provided to include a plurality of curved portions cp. Specifically, as shown in the upper part of FIG. 7, the heat dissipation wiring L2b includes nine curved portions cp in total. The nine curved portions cp are arranged at predetermined intervals along the circumferential direction. For this reason, the heat dissipation wiring L2b is provided to meander in a wave shape along the front surface S11 as a whole. As shown in the upper part of FIG. 7, the heat dissipation wiring L2b is disposed to be largely bent substantially along the front surface S11 as a whole. Similarly to the heat dissipation wiring L2b the heat dissipation wiring L5b includes nine curved portions cp, and is provided to meander in a wavy shape along the back surface S12. Further, the heat dissipation wiring L5b is disposed to be bent substantially along the back surface S12 as a whole.

The substrate 31b according to the third embodiment described above achieves the same effects as the substrate 31 according to the first embodiment. In addition, since the heat dissipation wirings L2b and L5b are provided to include the plurality of curved portions cp, larger surface areas of the heat dissipation wirings L2b and L5b can be secured as compared with a configuration in which the heat dissipation wirings L2b and L5b are bent as a whole without a plurality of curved portions cp or a configuration in which the heat dissipation wirings L2b and L5b are provided in a linear shape without a plurality of curved portions cp.

### D. Other Embodiments

(D1) In each of the embodiments, the "installation portion" is the front surface S11 and the back surface S12, but the present disclosure is not limited thereto. The "installation portion" may be only one of the front surface S11 and the back surface S12. In addition, for example, the substrate main body 39 may have a configuration in which a plurality of layers are stacked, and a boundary surface between two adjacent layers among the plurality of layers may be the "installation portion". Also in such a configuration, by disposing the heat dissipation wiring to be bent along the boundary surface, the larger surface area of the heat dissipation wiring can be secured and the heat dissipation efficiency can be improved as compared with a configuration in which the heat dissipation wiring is disposed linearly. In addition, in such a configuration, as in the second embodiment and the third embodiment, by adopting a configuration in which the heat dissipation wiring includes a plurality of bent portions or curved portions, the larger surface area of the heat dissipation wiring can be secured, and the heat dissipation efficiency can be improved.

(D2) In each of the embodiments, the heat dissipation wirings L11, L12, L1 to L7, L2a, L5a, L2a, and L2b are also used as the power supply wirings, but the present disclosure is not limited thereto. The heat dissipation wiring may be provided as a dedicated wiring separately from the power supply wiring. In addition, both end portions of each of the heat dissipation wirings L11, L12, L1 to L7,L2a, L5a, L2a, and L2b are connected to another wiring or element, but one end portion may not be connected to another wiring or element and be in a disengaged state. Further, both end portions of the heat dissipation wiring may not be connected to another wiring or element. Also in such a configuration, since the heat dissipation wirings are provided in the vicinity of the plurality of first LEDs 32 or the plurality of second LEDs 33, the heat of the plurality of first LEDs 32 or the plurality of second LEDs 33 transferred via the substrate main body 39 can be dissipated by using the heat dissipation wirings.

(D3) In each of the embodiments, any one of the plurality of first LEDs 32 and the plurality of second LEDs 33 may be omitted. In such a configuration, among the heat dissipation wirings L11 and L12 and the heat dissipation wirings L1 to L7, L2a, L5a, L2b, and L5b, the heat dissipation wirings corresponding to the omitted LEDs may be omitted.

(D4) In each of the embodiments, the plurality of second LEDs 33 are positioned outside the plurality of first LEDs 32 in the radial direction, but the present disclosure is not limited thereto. The plurality of second LEDs 33 may be positioned inside the plurality of first LEDs 32 in the radial direction.

(D5) In each of the embodiments, the thicknesses of the heat dissipation wirings L11 and L12 may be increased similarly to the heat dissipation wirings L2, L5, L2a, L5a, L2b, and L5b. Further, the heat dissipation wirings L11 and L12 may include a plurality of bent portions bp similarly to the heat dissipation wirings L2a and L5a according to the second embodiment, or may include a plurality of curved portions cp similarly to the heat dissipation wirings L2b and L5b according to the third embodiment.

(D6) In each of the embodiments, the illumination device 200 is provided in the grip portion 110, but the present disclosure is not limited thereto. For example, a configuration may be used in which the illumination device 200 may be provided in any portion of the steering wheel 100, such as the boss portion 130 and the spoke portions 120. In this case, the shape and the configuration of the illumination device 200 can be appropriately changed in accordance with the size, shape, and the like of a place in which the illumination device 200 is provided. The position of the illumination device 200 is preferably a position that can be viewed directly by the driver. However, for example, in a case in which the light emitted from the illumination device 200 is reflected on a surface of any portion in the vehicle, for example, a surface of an instrument panel, and the reflected light can be viewed by the driver, the position of the illumination device 200 may be a position that cannot be viewed directly by the driver.

The present disclosure is not limited to the above embodiments, and can be implemented by various configurations without departing from the gist of the present disclosure. For example, the technical features in each embodiment corresponding to the technical features in the aspects described in the Summary can be replaced or combined appropriately in order to solve a part or all of the above problems or in order to achieve a part or all of the above effects. Further, unless the technical features are described as being essential in the present specification, the technical features can be appropriately deleted.

### REFERENCE SIGNS LIST

10 lens member

11 second emission surface

12 surrounding portion

13 protrusion

14 engaging hole

15 engaging wall

19 light emitting region

20 light guiding member

21 first light passage portion

22 second light passage portion

23 deflection portion

24 deflection surface

25 diffusion portion

30 light emitting portion

31, 31a, 31b substrate

32 first LED

33 second LED

39 substrate main body

40 base member

41 transmission inhibition portion

44 engaging claw

45 engaging wall

80 outer skin layer

100 steering wheel

110 grip portion

120 spoke portion

130 boss portion

200 illumination device

AX axis

C1 recess

CN1, CN2 connector

L1 to L7

L2a, L5a, L2b, L5b heat dissipation wiring

S1 first emission surface

S11 front surface

S12 back surface

S2 incident surface

SH steering shaft

bp bent portion

cp curved portion

g1, g2 group

p11, p12, p21, p22 end portion

What is claimed is:

1. A substrate for an illumination device to be mounted on a steering wheel, the substrate comprising:
a substrate main body;
a light emitting element provided on a surface of the substrate main body; and
a heat dissipation wiring comprising a material having a higher thermal conductivity than a thermal conductivity of the substrate main body, the heat dissipation wiring being provided in an installation portion that is at least one of: inside of the substrate main body; or an outer surface of the substrate main body, and the heat dissipation wiring being configured to dissipate heat generated from the light emitting element.

2. The substrate according to claim 1, wherein
the heat dissipation wiring serves as a power supply wiring for supplying power to the light emitting element.

3. The substrate according to claim 1, wherein
the substrate main body has an external shape in which a pair of arc-shaped outer edges along a circumferential direction of an annular grip portion of the steering wheel are positioned apart from each other in a radial direction of the grip portion,
the light emitting element comprises
a pair of first light emitting elements respectively provided at end portions of the substrate main body along the circumferential direction, and
a second light emitting element provided between the pair of first light emitting elements in the circumferential direction and provided at a position different from the positions of the pair of first light emitting elements in the radial direction, and
the heat dissipation wiring is provided between the pair of first light emitting elements in the circumferential direction, and is provided at a position different from the position of the second light emitting element in the radial direction.

4. The substrate according to claim 1, wherein
the installation portion includes the outer surface, and
the heat dissipation wiring is disposed to be bent along the outer surface.

5. The substrate according to claim 2, wherein
the installation portion includes the outer surface, and
the heat dissipation wiring is disposed to be bent along the outer surface.

6. The substrate according to claim 3, wherein
the installation portion includes the outer surface, and
the heat dissipation wiring is disposed to be bent along the outer surface.

7. The substrate according to claim 4, wherein
the heat dissipation wiring is provided to include a plurality of bent portions or a plurality of curved portions.

8. The substrate according to claim 5, wherein
the heat dissipation wiring is provided to include a plurality of bent portions or a plurality of curved portions.

9. The substrate according to claim 6, wherein
the heat dissipation wiring is provided to include a plurality of bent portions or a plurality of curved portions.

10. The substrate according to claim 1, wherein
the substrate main body has a configuration in which a plurality of layers are stacked,
the installation portion includes a boundary surface between two adjacent layers among the plurality of layers, and
the heat dissipation wiring is disposed to be bent along the boundary surface.

11. The substrate according to claim 2, wherein
the substrate main body has a configuration in which a plurality of layers are stacked,
the installation portion includes a boundary surface between two adjacent layers among the plurality of layers, and
the heat dissipation wiring is disposed to be bent along the boundary surface.

12. The substrate according to claim 3, wherein
the substrate main body has a configuration in which a plurality of layers are stacked,
the installation portion includes a boundary surface between two adjacent layers among the plurality of layers, and
the heat dissipation wiring is disposed to be bent along the boundary surface.

13. The substrate according to claim 10, wherein
the heat dissipation wiring is provided to include a plurality of bent portions or a plurality of curved portions.

14. The substrate according to claim 11, wherein
the heat dissipation wiring is provided to include a plurality of bent portions or a plurality of curved portions.

15. The substrate according to claim 12, wherein
the heat dissipation wiring is provided to include a plurality of bent portions or a plurality of curved portions.
